(19) United States
(12) Patent Application Publication
(10) Pub. No.: US 2014/0264915 A1
(43) Pub. Date: Sep. 18, 2014

(54) Stacked Integrated Circuit System

(71) Applicants: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(72) Inventors: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(21) Appl. No.: 13/833,627

(22) Filed: Mar. 15, 2013

(51) Int. Cl. H01L 25/18

(52) U.S. Cl. CPC H01L 25/18
USPC 257/774

(57) ABSTRACT

A stacked integrated circuit system comprises a first chip with first average pattern density comprising memory cells, a second chip with second average pattern density comprising logic circuitries for the memory cells and a functioning unit and a plurality of through-silicon vias within one of the first chip and second chip to electrically connect the first chip and the second chip, wherein the memory cells of the first chip and the logic circuitries of the second chip are designed to be used collectively in order to perform complete memory functions, and wherein the first average pattern density is higher than the second average pattern density.

### FIELD OF THE INVENTION

The present invention relates to a stacked integrated circuit system and particularly to a stacked integrated circuit system using through-silicon vias.

### BACKGROUND OF THE INVENTION

To save precious layout space or increase interconnection efficiency, multiple chips of integrated circuits (ICs) can be stacked together as a single IC package. To that end, a three-dimensional (3D) stack packaging technology is used to package the chips of integrated circuits. Through-silicon vias (TSVs) are widely used to accomplish the 3D stack packaging technology. A through-silicon via is a vertical conductive via completely passing through a silicon wafer, a silicon board, a substrate of any material or die. Nowadays, a 3D integrated circuit (3D IC) is applied to a lot of fields such as memory stacks, image sensors or the like.

Although through-silicon vias come with many advantages, they also bring some issues into integrated circuits. For example, their gigantic size (hundred times bigger than traditional transistors) compared to their neighbors such as transistors, interconnections etc. would waste a lot of layout space. The more space they waste, the bigger a chip will be. Nowadays, all the electronic devices are expected to be small so wasting space is definitely not a smart idea. Therefore, there is a need to reorganize other devices to make up for the spaces wasted.

### SUMMARY OF THE INVENTION

In one embodiment of the present invention, a stacked integrated circuit system is provided to comprise a first chip with first average pattern density comprising memory cells, a second chip with second average pattern density comprising logic circuitries for the memory cells and a functioning unit and a plurality of through-silicon vias within one of the first chip and second chip to electrically connect the first chip and the second chip, wherein the memory cells of the first chip and the logic circuitries of the second chip are designed to be used collectively in order to perform complete memory functions, and wherein the first average pattern density is higher than the second average pattern density.

In another embodiment of the present invention, a stacked integrated circuit system is provided to comprise a first chip comprising memory cells, a second chip comprising a first part of logic circuitries for the memory cells, a third chip comprising a second part of logic circuitries for the memory cells and a plurality of through-silicon vias within one of the first chip, second chip and third chip to electrically connect the first chip, the second chip and the third chip, wherein the memory cells of the first chip, the first part of logic circuitries of the second chip and the second part of logic circuitries of the third chip are designed to be used collectively in order to perform complete memory functions.

In still another embodiment of the present invention, a stacked integrated circuit system is provided to comprise a first chip only comprising analogue circuitries, a second chip only comprising digital circuitries and a plurality of through-silicon vias within one of the first chip and second chip to electrically connect the first chip and the second chip, wherein the analogue circuitries of the first chip and the digital circuitries of the second chip are designed to be used collectively in order to perform complete functions.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 shows a schematic floorplan of a traditional memory bank in accordance with prior art;

FIG. 2 shows a cross-sectional schematic view of the stacked integrated circuit (IC) unit in accordance with an embodiment of the present invention;

FIG. 3 shows a schematic view of two chips before stacking together in accordance with an embodiment of the present invention;

FIG. 4 shows a schematic view of two chips before stacking together in accordance with another embodiment of the present invention;

FIG. 5 shows a cross-sectional schematic view of transistor-level of integrated circuits;

FIG. 6 shows a cross-sectional schematic view of transistor-level and interconnect-level of integrated circuits;

FIG. 7 shows a cross-sectional schematic view of the stacked integrated circuit (IC) unit in accordance with another embodiment of the present invention.

### DETAILED DESCRIPTION OF PREFERRED EMBODIMENTS

The following is the detailed description of the preferred embodiments of this invention. All the elements, sub-elements, structures, materials, arrangements recited herein can be combined in any way and in any order into new embodiments, and these new embodiments should fall in the scope of this invention defined by the appended claims. A person skilled in the art, upon reading this invention, should be able to modify and change the elements, sub-elements, structures, materials, arrangements recited herein without being apart from the principle and spirit of this invention. Therefore, these modifications and changes should fall in the scope of this invention defined only by the following claims.

There are a lot of embodiments and figures in this application. To avoid confusions, similar components are represented by same or similar numerals. To avoid complexity and confusions, only one of the repetitive components is marked. Figures are meant to deliver the principle and spirits of this invention, so the distance, size, ratio, shape, connection relationship, etc. are examples instead of realities. Other distance, size, ratio, shape, connection relationship, etc. capable of achieving the same functions or results can be adopted as equivalents.

Please refer to FIG. 1, which shows a schematic floorplan of a traditional memory bank in accordance with prior art. In the center of the bank are a plurality of memory arrays and a plurality of sense amplifiers adjacent to the memory arrays. Each memory array comprises hundreds of memory cells such as SRAM cells and DRAM cells and each SRAM cell or DRAM cell comprises at least one transistor. In the periphery region of the memory bank are logic circuitries comprising row decoders, buffers and input/output (I/O). For a memory chip, it may comprise hundreds or thousands of this kind of memory banks.

In a single die (or chip), the pattern density, pattern pitch and the quantity of interconnect layers depend on the complexity of the circuitry, the generation of manufacturing process, the layout approach adopted, the performance required. In a die (or chip) with memory arrays and logic circuitry region as shown in FIG. 1, the highest pattern density and the finest pattern pitch would be found in the memory arrays. Therefore, using the same manufacturing process to produce the memory arrays and logic circuitry region shown in FIG. 1 would often lead to non-uniformity in thickness, in critical dimention (CD), in dopant distribution . . . etc, thereby leading to low yield. Furthermore, in order to produce the memory arrays with higher pattern density and finer pitch, high precision of process control and high capability of equipments are demanded, hence high cost. Except that, memory cells such as DRAM and SRAM cells usually require less layers of interconnects than the logic circuitry. Interconnects serve as the streets and highways of the integrated circuit (IC), connecting elements of the IC into a functioning whole and to outside, and alternating layers of interconnects are usually orthogonal with each other. Although interconnects are important to the IC, too many layers of interconnects may also cause some problems such as high parasitic capacitance to slow down the chip, crosstalk to become noise affecting signals, and heat dissipation issues. Hence, there is a need to solve the foregoing issues.

Now please refer to FIG. 2, which shows a schematic cross-sectional view of the stacked integrated circuit (IC) system in accordance with an embodiment of the present invention. In FIG. 2, chip 1 and chip 2 are stacked together and electrically connected using through-silicon vias (TSVs) 100 and micro bumps/bumps 200. Chip 1 and chip 2 bear integrated circuits designed to be used collectively in order to perform complete memory functions, that is, just one of chip 1 and chip 2 is incapable of functioning as memories properly. In one embodiment shown in FIG. 3, chip 1 may bear all the memory cells such as DRAM and SRAM cells and chip 2 may bear all the logic circuitries such as sense amplifiers, local column decoders, local row decoders, global column decoders, global row decoders, buffers and input/outputs. Furthermore, chip 2 not only bears the logic circuitries for controlling chip 1 and working with chip 1 but also bears another functioning unit such as a central processor unit (CPU) or a graphic processing unit (GPU) or a heat sink or a basic input/output system (BIOS). In a lot of known arts, memory cells and their logic circuitries are put into the same chip and a functioning unit such as a central processor unit is put into another chip. It is noted that each DRAM cell may comprise at least a transistor and a capacitor (either trench-type or stack-type capacitor) and each SRAM may comprise several transistors (for a 6T SRAM, 6 transistors), and within chip 1 there would be hundreds or thousands of these cells tightly arranged against each other.

In another example of the present invention shown in FIG. 4, the sense amplifiers are put into the chip 1 with memory cells because their tight noise margin compared with decoders and inputs/outputs. Not only that, the functioning unit in the chip 2 is divided into two parts, the first part and the second part. The first part is put into chip 1 together with memory cells and the second part is put into chip 2 together with logic circuitries for memory cells.

Now please refer to FIG. 5, which shows a cross-sectional schematic view of transistor-level of integrated circuits. As shown in FIG. 5, assume both chip 1 and chip 2 have a plurality of transistors 20 formed on a substrate 10 and each transistor 20 has at least one gate electrode 22 and one source/drain (S/D) 24. The integrated circuits on chip 1 has a first average pattern density for gate electrode 22 (later may be referred to as average pattern density for abbreviation), a first mininum pattern pitch for gate electrode 22 (later may be referred to as minimum pattern pitch for abbreviation). The integrated circuits on chip 1 has a second average pattern density for gate electrode 22, a second mininum pattern pitch for gate electrode 22. The average pattern density for gate electrode 22 is defined as the area occupied by all the gate electrodes 22 divided by the entire area of the whole chip. The minimum pattern pitch for gate electrode 22 is defined as smallest pitch for gate electrode 22 that can be found within the whole chip. The first average pattern density for gate electrode 22 is different from the second average pattern density for gate electrode 22, and the first mininum pattern pitch for gate electrode 22 is also different from the second mininum pattern pitch for gate electrode 22.

Then please refer to FIG. 6, which shows a cross-sectional schematic view of transistor-level and interconnect-level of integrated circuits. FIG. 6 provides a simple relationship between the substrate 10, transistors 20 and metal 1 (M1) through metal 6 (M6). As shown in FIG. 4, the contact couples the source/drain (S/D) 24 to the metal 1 (M1), the via 1 (V1) couples the metal 1 (M1) to metal 2 (M2), the via 2 (V2) couples the metal 2 (M2) to the metal 3 (M3), the via 3 (V3) couples the metal 3 (M3) to metal 4 (M4), the via 4 (V4) couples the metal 4 (M4) to metal 5 (M5) and the via 5 (V5) couples the metal 5 (M5) to the metal 6 (M6), so the number of interconnect layers shown in FIG. 4 is 6 in accordance with the highest metal layer M6. The integrated circuits on chip 1 has a first number of interconnect layers. The integrated circuits on chip 2 has a second number of interconnect layers. The first number is different from the second number.

In a preferable embodiment shown in FIG. 2, the first average pattern density for gate electrode 22 is higher than the second average pattern density for gate electrode 22, the first minimum pattern pitch for gate electrode 22 is smaller than the second minimum pattern pitch for gate electrode 22, and first number is smaller the second number.

Although in FIG. 2 chip 1 is bigger than chip 2 in size, the sizes of chip 1 and chip 2 are not limited. For example, chip 1 and chip 2 may be equivalent in size. Also, in FIG. 2 chip 2 is on top of chip 1 and bears TSVs 100 and micro bumps/bumps 200 but the present invention is not limited thereto. TSVs 100 and micro bumps/bumps 200 may also be disposed in/on the chip 1 below chip 2.

Now refer to FIG. 7, which shows a cross-sectional schematic view of the stacked integrated circuit (IC) system in accordance with another embodiment of the present invention. The embodiment of FIG. 7 is similar to the embodiment of FIG. 2 except there is a newly added chip 3 stacked on top of the chip 1 using TSVs 100′ and micro bumps/bumps 200′ in/on chip 3. Chip 1, chip 2 and chip 3 bear integrated circuits designed to be used collectively in order to perform complete memory functions, that is, just one of chip 1, chip 2 and chip 3 is incapable of functioning properly.

For example, chip 1 may bear all the memory cells such as DRAM and SRAM cells and sense amplifiers, chip 2 may bear some of the logic circuitries such as local row decoders, local column decoders, buffers, and chip 3 may bear the rest of the logic circuitries such as inputs/outputs, global bank decoder and ESD devices. The integrated circuits on chip 3 has a third average pattern density for gate electrode 22, a third minimum pattern pitch for gate electrode 22 and a third number of interconnect layers. The third average pattern density for gate electrode 22 is different from the second and first pattern densities for gate electrode 22; the third minimum pattern pitch for gate electrode 22 is different from the second and first minimum patter pitches for gate electrode 22; and the third number is different from the second and first numbers.

In a preferable embodiment shown in FIG. 7, the first average pattern density for gate electrode 22 is the highest, the second average pattern density for gate electrode 22 is between the first pattern density and the third pattern density, and the third average pattern density for gate electrode 22 is the lowest. Same order is for the minimum pattern pitch for gate electrode 22. As to the number of interconnect layers, first number is the lowest while the second number and the third number may be the same or different.

Similar to the embodiment of FIG. 2, the sizes of chips are not limited. For example, chip 2 and chip 3 may be equivalent in size. Also, in FIG. 7 chip 2 and 3 are on top of chip 1 and bear TSVs 100/100′ and micro bumps/bumps 200/200′ but the present invention is not limited thereto. TSVs 100/100′ and micro bumps/bumps 200/200′ may also be disposed in/on the chip 1 below chip 2 and 3. Or, the chip 3 shown in FIG. 7 is a Si interposer without active devices thereon. In this case, chip 1 and chip 2 together can perform complete memory functions and central/graphic processing functions while chip 3 merely plays the role of interface between chip 1 and 2 and an outside environment. Under this circumstance, chip 3 may comprise TSVs, micro bumps/bumps, interconnects, passive devices. Since chip 3 has no active devices such as MOS transistors, it has no average pattern density for gate electrode 22, no minimum pattern pitch for gate electrode 22 and its number of interconnect layers would be small.

In this way, the present invention may apply different generations of process to different chips, so uniformity within each chip can be improved and cost may be reduced. Furthermore, the number of interconnect layers may be customized for each chip, so sensitive memory cells such as

DRAM and SRAM may get less noise. It is worth mentioning that sometimes analogue circuitries and digital circuitries also have very different layout densities, noise margins, different numbers of interconnect layers hence it is possibly to apply the present invention to an integrated circuit system comprising both analogue and digital circuitries. By applying the principles of the present invention, the analogue circuitries would be put in one chip, the digital circuitries would be put in the other chip and these two chips would be electrically connected together by TSVs to perform a series of complete functions that can not be performed by the analogue circuitries alone or by the digital circuitries alone. The chip with digital circuitries and the chip with analogue circuitries may have different average pattern density for gate electrodes, different minimum pattern pitch for gate electrodes and/or different numbers of interconnect layers.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A stacked integrated circuit system, comprising:
a first chip with first average pattern density, comprising memory cells;
a second chip with second average pattern density, comprising logic circuitries for the memory cells and a functioning unit; and
a plurality of through-silicon vias within one of the first chip and second chip to electrically connect the first chip and the second chip,
wherein the memory cells of the first chip and the logic circuitries of the second chip are designed to be used collectively in order to perform complete memory functions, and
wherein the first average pattern density is higher than the second average pattern density.

2. The stacked integrated circuit system of claim 1, wherein the memory cells are DRAM or SRAM cells.

3. The stacked integrated circuit system of claim 2, wherein the first chip further comprises sense amplifiers for the memory cells.

4. The stacked integrated circuit system of claim 3, wherein the logic circuitries comprise local column decoders, local row decoders, global column decoders, global row decoders, buffers and input/outputs.

5. The stacked integrated circuit system of claim 2, wherein the logic circuitries comprise sense amplifiers, local column decoders, local row decoders, global column decoders, global row decoders, buffers and input/outputs.

6. The stacked integrated circuit system of claim 1, wherein the functioning unit comprises a central processor unit (CPU) or a graphic processing unit (GPU), a heat sink or a basic input/output system (BIOS).

7. The stacked integrated circuit system of claim 1, wherein the first chip has a first number of interconnect layers and the second chip has a second number of interconnect layers, and the first number is smaller than the second number.

8. The stacked integrated circuit system of claim 1, wherein the first chip is bigger than the second chip in size.

9. A stacked integrated circuit system, comprising:
a first chip comprising memory cells;
a second chip comprising a first part of logic circuitries for the memory cells;
a third chip comprising a second part of logic circuitries for the memory cells; and
a plurality of through-silicon vias within one of the first chip, second chip and third chip to electrically connect the first chip, the second chip and the third chip,
wherein the memory cells of the first chip, the first part of logic circuitries of the second chip and the second part of logic circuitries of the third chip are designed to be used collectively in order to perform complete memory functions.

10. The stacked integrated circuit system of claim 9, wherein the memory cells are DRAM and SRAM cells.

11. The stacked integrated circuit system of claim 10, wherein the first chip further comprises sense amplifiers.

12. The stacked integrated circuit system of claim 11, wherein the first part of logic circuitries comprise local row decoders, local column decoders, buffers.

13. The stacked integrated circuit system of claim 11, wherein the second part of logic circuitries comprise inputs/outputs, global bank decoder and ESD devices.

14. The stacked integrated circuit system of claim 9, wherein the first chip, second chip and third chip have first average pattern density, second average pattern density and third average pattern density respectively and the first average pattern density is larger than the second and third average pattern density.

15. The stacked integrated circuit system of claim 9, wherein the first chip, second chip and third chip have first minimum pattern pitch, second minimum pattern pitch and third minimum pattern pitch respectively and the first minimum pattern pitch is smaller than the second and third minimum pattern pitch.

16. The stacked integrated circuit system of claim 9, wherein the first chip is bigger than the second chip and is bigger than the third chip in size.

17. A stacked integrated circuit system, comprising:
a first chip only comprising analogue circuitries;
a second chip only comprising digital circuitries; and
a plurality of through-silicon vias within one of the first chip and second chip to electrically connect the first chip and the second chip,
wherein the analogue circuitries of the first chip and the digital circuitries of the second chip are designed to be used collectively in order to perform complete functions.

18. The stacked integrated circuit system of claim 17, wherein the first chip and the second chip have a first average pattern density and a second average pattern density respectively, and the first average pattern density is different from the second average pattern density.

19. The stacked integrated circuit system of claim 17, wherein the first chip and the second chip have a first minimum pattern pitch and a second minimum pattern pitch respectively, and the first minimum pattern pitch is different from the second minimum pattern pitch.

20. The stacked integrated circuit system of claim 17, wherein the first chip and the second chip have a first number of interconnect layers and a second number of interconnect layers respectively, and the first number is different from the second number.
